(19) United States
(12) Patent Application Publication
(10) Pub. No.: US 2025/0131150 A1
(43) Pub. Date: Apr. 24, 2025

(54) OPTIMIZATION OR IMPROVEMENT OF THE EFFICIENCY OF A SYSTEM FOR PRESSURIZED FLUID COMPRISING A PRESSURIZED PIPING NETWORK UNDER DYNAMIC LOAD

(71) Applicant: ATLAS COPCO AIRPOWER, NAAMLOZE VENNOOTSCHAP, Wilrijk (BE)

(72) Inventors: Philippe GEUENS, Wilrijk (BE); Filip DE VOS, Wilrijk (BE)

(73) Assignee: ATLAS COPCO AIRPOWER, NAAMLOZE VENNOOTSCHAP, Wilrijk (BE)

(21) Appl. No.: 18/834,517

(22) PCT Filed: Jan. 17, 2023
(86) PCT No.: PCT/IB2023/050396

§ 371 Date: Jul. 30, 2024

(30) Foreign Application Priority Data
Feb. 9, 2022 (BE) 2022/5086

(51) Int. Cl. G06F 30/18; F04B 49/06

(52) U.S. Cl. CPC G06F 30/18; F04B 49/065

(57) ABSTRACT

A method for optimizing a system for pressurized fluid including a piping network which is provided with an inlet and multiple outlets, subjected to a varying load. The method includes determining minimum pressures (P_{POi}^{req}) required at the outlets (3); determining a measuring period (ΔTₘ); measuring outlet pressures (P_{POi} ) during the measuring period (ΔTₘ); calculating corresponding overpressures (OP_{POi}); finding the minimal overpressure (OP_{POi}^{min}); finding the smallest minimal overpressure (SMO) occurring in the piping network (1); decreasing the inlet pressure (P_{IN}) with SMO, when SMO>0; and, evaluating other rearrangements when SMO≤0.

### TECHNICAL FIELD

The present invention relates to the field of systems for pressurized fluid comprising a pressurized piping network, such as a pneumatic network. Such a system for pressurized fluid comprises a piping network with at least one main pipe inlet through which a pressurized fluid is supplied to the piping network for example by means of a pressurizing machine of the system for pressurized fluid, such as a compressor, and one or more pipe outlets through which pressurized fluid is delivered to one or more corresponding user devices or appliances which are located at user locations spaced apart from one another. The pressurized fluid taken by the different user devices or appliances varies over time, resulting in a dynamic load at the pipe outlets of the piping network.

### BACKGROUND

In many applications a pressurized fluid, mostly pressurized air, is used to drive certain pneumatically and/or hydraulically driven user devices or appliances, such as manufacturing or servicing tools, robots, machines, brakes and so on.

These pneumatically and/or hydraulically driven tools can be manually manipulated tools such as pneumatically and/or hydraulically driven wrenches, torque tools, screwdrivers, drills, grinders, sanders, polishers, percussive tools, compression tools, air motors, jacks, lifting tools and so on.

In other cases, the tools or machines are automatically manipulated tools or machines, such as pneumatically and/or hydraulically driven robot arms or robots, or computer-controlled manufacturing benches, which comprise pneumatically and/or hydraulically driven tools or arms that automatically execute the required actions and movements.

The amount of pressurized fluid power needed by said tools or machines differs very much from application to application. Different types of tools or machines have different nominal, maximal and minimal power needs. Also, during one operation with such a machine or tool the power needs vary according to the load exerted on the machine or tool or the resistance felt by the machine or tool.

Multiple such user devices or appliances driven by a pressurized fluid are often used simultaneously at locations which are spaced from one another at distances which can be large or very large (up to several 100 meters or kilometers) or which can be smaller (meters or several 10 meters) depending on the application.

For example, in certain manufacturing plants or assembly lines the manufacturing or assembly of a product requires different processing stages which are executed at different workstations, distributed over the entire surface of the plant or along the assembly line. Pre-processed parts of the product or semi-finished products are passed from workstation to workstation until a finished product is achieved. The workstations are therefore often placed in consecutive order in accordance with the sequence of the processing stages.

Also, in service centers or workshops for maintenance or for reparation of machines or vehicles, service operators typically work simultaneously at different posts spread over the entire service center or workshop for the reparation or maintenance of the concerned machine or vehicle.

In the construction industry or in mining operations, teams are often working at locations which are dispersed and widespread over the construction site or mining plant for executing often quite heavy tasks.

For providing pressurized fluid, usually pressurized air, to the different user locations, posts, workstations and so on, where user devices or appliances need the pressurized fluid for driving tools or machines, usually a single source or a limited number of sources of pressurized fluid is used.

Typically, such a source of pressurized fluid is a pressurizing machine that pressurizes an incoming non-pressurized fluid into an outgoing pressurized fluid. Such a pressurizing machine can for example be a compressor for compressing air at atmospheric pressure into air at a higher pressure. The pressurizing machine can also by a pump or any other machine by which a fluid can be pressurized.

The source of pressurized fluid can also be a combination of pressurizing machines or a combination of a pressurizing machine and a pressure vessel, put in series after one another, and so on.

In another example, it is also possible that the source of pressurized fluid is not a pressurizing machine, but an existing source of pressurized fluid, such as the water in a lake behind a barrage dam.

In order to connect the single source or limited number of sources of pressurized fluid with the different user devices and appliances, which need pressurized fluid, and which are spaced from one another at different user locations such as workstations, service posts, mining sites, and so on, a piping network is usually provided.

This piping network has at least one main pipe inlet, which is connected to the single source or limited number of sources of pressurized fluid.

As a rule, a main pipe piece extends from the main pipe inlet. This main pipe piece is branched into several pipe branches, which can also be further branched into pipe subbranches and so on, resulting in a number of pipe branches and pipe subbranches corresponding to the number of user locations to which pressurized fluid has to be provided.

These pipe branches and pipe subbranches are ending in a pipe outlet and the concerned user devices or appliances at the different user locations are connected to such a pipe outlet.

It is a known phenomenon that during transport of pressurized fluid from the main pipe inlet of such a piping network to an afore-mentioned pipe outlet a certain pressure drop occurs.

The pressure drop experienced at a certain pipe outlet is the difference between the fluid pressure present at the main pipe inlet and the fluid pressure experienced at the concerned pipe outlet.

This pressure drop is usually different for the different pipe outlets and depends on several factors and varies over time due to changing demands at the pipe outlets during operation.

The pressure drop is caused by friction loss of the fluid during flow in the pipe.

A very important factor influencing said pressure drop is the flow rate of fluid or the velocity of the fluid through the pipe piece concerned.

Another factor that plays a certain role is the viscosity of the fluid.

Still another important factor that influences the pressure drop between the main pipe inlet and a certain pipe outlet of the piping network, is the pipe length of the concerned pipe piece between the main pipe inlet and the concerned pipe outlet.

Still other factors influencing said pressure drop are the roughness of the pipe in the concerned pipe piece, the diameter of the concerned pipe piece or changes in diameter in the concerned pipe piece between the main pipe inlet and the concerned pipe outlet.

Also, the number of bends in the concerned pipe piece, the presence of other mechanical components such as valves, flow meters, couplings, and so on, in the concerned pipe piece play an important role.

Still another factor that possibly influences the pressure or pressure drop is a variation of the fluid pressure at the main pipe inlet.

For example, when the demand of pressurized fluid at the totality of pipe outlets is very big, it is possible that the source of pressurized fluid cannot follow this total demand of pressurized fluid at the main pipe inlet and it is therefore possible that the fluid pressure at this main pipe inlet temporarily decreases, until the demand corresponds again with or is lower than the capacity of delivering pressurized fluid by the source of pressurized fluid.

In short, it is rather difficult or almost impossible to predict the varying pressure or pressure drops in a precise way at all the pipe outlets.

Furthermore, it is important to understand that some user devices or appliances connected to a pipe outlet of the piping network often require a minimal required fluid pressure at their inlet to be functional.

This means that the inlet pressure at the main pipe inlet should be at all times sufficiently high so that, when the pressure drops in the pipe pieces to the different pipe outlets are taken into account, there is still enough outlet pressure left at every and each pipe outlet and at each instance during the time of operation at the different user locations.

This outlet pressure should in any circumstance at least be higher at each such user location than the minimum pressure required at the concerned user location so to provide pressurized fluid at a pressure which is sufficiently high, so that the concerned user devices or appliances can still function adequately, even when they are used at their highest load.

The needed inlet pressure at the main pipe inlet of the piping network could for example be determined theoretically by calculating what this needed inlet pressure should be in circumstances wherein the maximum load is simultaneously applied at all the pipe outlets or user locations.

In practice however, this situation of a maximal load of the piping network wherein simultaneously at all the user locations a maximal load is applied, will never or almost never exist.

Indeed, in normal circumstances during operation pressurized fluid is taken during certain periods at some of the pipe outlets, while other pipe outlets stay closed. During other periods of the operation other pipe outlets might open or some of the formerly open pipe outlets might close.

Furthermore, even the load taken at each of the pipe outlets in the non-closed situation of such a pipe outlet is usually varying or fluctuating during operation and such a load is usually not equal to the maximally allowable load during the entire duration of the operation.

As a result, a needed inlet pressure calculated theoretically in the above-mentioned way will be in practice unnecessarily high resulting in energy waste.

One can easily understand that it is not easy to determine how high the inlet pressure at the main pipe inlet should in practice at least be during operation, so that the needed load can be taken at the different pipe outlets in a safe way and without interruption of the operations at any of the user locations due to a lack of pressure at a concerned pipe outlet.

Obviously, when the source of pressurized fluid, which supplies the needed inlet pressure at the main pipe inlet of the piping network, comprises a pressurizing machine such as a compressor or pump, energy, for example electric energy, is needed to drive the pressurizing machine. The inlet pressure of the piping network is in that case of course the same as the outlet pressure of the pressurizing machine.

A lot of energy can be saved when the outlet pressure of the pressurizing machine or the inlet pressure of the piping network can be decreased and, consequently, also the costs related to the supply of energy can be reduced significantly.

In particular, the following formula gives an idea of the cost reduction obtained when a pressure reduction of Δp at the outlet of the pressurizing machine can be applied:

$$Cost reduction = ( \frac{Δ p}{0.1} ) \times V \times {R}_{h} \times 0.35 \times 0.007 \times {C}_{e}$$

The different parameters are:
Δp=pressure reduction at the outlet of the compressor
V=volume flow rate
Rₕ=running hours
Cₑ=cost of electricity

According to the state of the art a good method for improving or optimizing the energy and cost efficiency of a system for pressurized fluid with a pressurized piping network which is subject to varying load at multiple pipe outlets of the piping network is not yet existing.

In particular, there is no good known method for setting the inlet pressure at the main piping inlet of the piping network at an optimized inlet pressure in a way which is adapted to the varying demands of pressurized fluid occurring in reality at the different pipe outlets of the piping network during operation.

Also, no good method exists to evaluate possible adaptations of an existing piping network for optimizing the energy and cost efficiency of the system for pressurized fluid in which the pressurized piping network is incorporated.

### SUMMARY OF THE INVENTION

The present invention aims to provide a method for optimizing or improving the efficiency of a system for pressurized fluid, such as a compressed air system, comprising a pressurized piping network that is subjected to a varying load, this of course with the intention of minimizing energy costs related to the passage of pressurized fluid through the piping network.

In particular, it is a possible aim of the present invention to develop a method by which pressure drops can be evaluated occurring in an existing pressurized piping network during operation with the piping network for delivery of pressurized fluid to user locations and to look for possibilities by which the needed inlet pressure at the main pipe inlet of the piping network can be decreased.

Another possible aim of the invention is to come to a method for evaluating possible modifications to an existing piping network of a system for pressurized fluid by which pressure drops can be reduced or lack of pressure at pipe outlets can be avoided with the intention to optimize the energy and cost efficiency of the concerned system for pressurized fluid, whereby installation costs and financial gains from reduced energy costs are evaluated with respect to one another.

To this end, the present invention relates to a method for optimizing or improving the energy and cost efficiency of a system for pressurized fluid which comprises a pressurized piping network which is provided with a main pipe inlet and multiple pipe outlets which are located at user locations which are spaced from one another, wherein at the main pipe inlet of the piping network an inlet pressure is provided by a source of pressurized fluid of the system for pressurized fluid and wherein the piping network is subjected to a varying load at the pipe outlets due to varying demands of pressurized fluid during operation of user devices connected to the piping outlets at the user locations, wherein the method comprises the steps of:
a.—determining for one or more pipe outlets the minimum pressure which is required at any time at the corresponding user location, so that operations at that user location can take place uninterruptedly;
b.—determining a measuring period, corresponding to a typical duty cycle of the piping network, during which pressures at the main pipe inlet and the pipe outlets will be measured;
c.—measuring the pressure at the main pipe inlet and at the concerned pipe outlets during the measuring period;
d.—calculating the difference during the measuring period between the possibly changing pressure at each concerned pipe outlet and the corresponding minimum pressure which is required at any time at the corresponding user location, so to find the corresponding overpressure at the concerned pipe outlet which is possibly varying during the measuring period;
e.—finding for each concerned pipe outlet the minimal overpressure occurring during the measuring period so to obtain a series of minimal overpressures composed of the minimal overpressures of each concerned pipe outlet;
f.—finding the smallest minimal overpressure occurring in the piping network during the measuring period;
g.—evaluating whether the smallest minimal overpressure occurring in the piping network during the measuring period, is bigger than zero or not;
h.—when the smallest minimal overpressure is bigger than zero, making the proposal to decrease the inlet pressure of the piping network with an amount which is equal to or slightly larger or slightly smaller than the smallest minimal overpressure; and,
i.—when the smallest minimal overpressure is zero or lower than zero, making no further efforts for improving or optimizing the efficiency of the system for pressurized fluid or making an evaluation of possible rearrangements to the piping network for increasing the energy and cost efficiency of the system for pressurized fluid.

A great advantage of such a method according to the invention is that it allows for an improvement or optimization of the efficiency of a system for pressurized fluid which comprises a pressurized piping network based on a monitoring of actual pressure loads measured in real live conditions, during a typical duty cycle.

In that way, overestimation of the needed inlet pressure at the main pipe inlet of the piping network of the system for pressurized fluid can be avoided.

Indeed, an estimation of the inlet pressure can for example be made on a theoretical basis by calculating the needed inlet pressure under conditions wherein a maximum load is applied simultaneously at all pipe outlets. However, such an estimation of the needed inlet pressure will usually be much too high, since in practice such conditions will very rarely occur.

With a method in accordance with the invention the needed inlet pressure can be determined based on data from real measurements of the pressure at pipe outlets during use of the piping network.

Another advantage of such a method according to the invention is that it allows for the detection of critical parts of the piping network with high pressure needs and that with the method also measures can be taken in order to rearrange the piping network, so to render such a concerned part or parts of the piping network less critical.

Still another important advantage of such a method according to the invention is that a lot of energy can be saved and, as a consequence, operation costs, CO₂ emission, . . . can be reduced a lot.

In a preferred embodiment of a method of the invention the pressure at the main pipe inlet and at the concerned pipe outlets are measured in a synchronous way during the measuring period in step c of the method.

It is of course only by simultaneously measuring the pressure at the main pipe inlet and at the concerned pipe outlets during a typical duty cycle that a correct view of the evolution is obtained of the real pressure drops occurring in the pressurized piping network.

Preferably, the pressure measurement is executed during the complete measuring period, for example in an analogue way, so that not any critical situation is missed of the presence of a high pressure need at the main pipe inlet, due to the simultaneous occurrence of high or maximum pressure loads at the pipe outlets during the duty cycle.

In a possible preferred embodiment of a method in accordance with the invention, the measurement of pressures during the measuring period in step c of the method is a digital pressure measurement which is executed simultaneously at the different concerned pipe outlets and this at discrete points in time during the measuring period. The calculating and finding in steps d and e of the method are in this case executed on this group of discrete digital measurements.

An advantage of a digital measurement of pressure is that such a way of measuring results in digital data of the measured pressure, which type of data is more adapted for further processing with the currently available data processing means, such as a computer.

It is obvious that the discrete points in time should be sufficiently near to one another so that critical pressure load situations are not overlooked. This is at present not an issue anymore since high level electronic measuring devices are anywhere available.

In a preferred method of the invention, after executing step h of the method, in the case the smallest minimal overpressure is bigger than zero, the inlet pressure is decreased by the proposed amount by adapting the pressure at the outlet of the source of pressurized fluid and steps c-i of the method are repeated.

A first advantage of such an embodiment of a method according to the invention is that the inlet pressure of the piping network is set to a lower level, which is possible since the smallest minimal overpressure at the pipe outlets is bigger than zero and in that manner energy and money are saved.

Usually, a piping network is designed such that the pressure drop in the piping network due to friction loss at its maximum load is not more than 3 to 5% over the entire pipe length from the main pipe inlet to the concerned pipe outlet.

In these conditions the smallest minimal overpressure at the pipe outlets is a good measure for the surplus of pressure available at the main pipe inlet and the error made by this supposition is negligible in these conditions.

Another advantage of such an embodiment of a method according to the invention is that the method is repeated by a reiteration through steps of the method for further improvement or optimization of the system for pressurized fluid, for example by executing steps of the method wherein an evaluation of one or more rearrangements of the piping network is made. Such a rearrangement can for example consist of a rearrangement of the diameter of a piping network part or can for example be a rearrangement by insertion of a pressure vessel or a rearrangement by replacement of parts like filters, regulators, lubricators, valves or other components in the piping network.

Another preferred aspect of a method in accordance with the invention is therefore that executing step i, in the case the smallest minimal overpressure is zero or smaller than zero, comprises an evaluation which involves a calculation of potential financial savings due to an increase in energy efficiency caused by a rearrangement of the piping network versus costs for rearranging the piping network.

In the case wherein the smallest minimal overpressure is zero or smaller than zero there is no surplus pressure available at the main pipe inlet of the piping network and in the whole period during which the minimal overpressure at the concerned pipe outlet is zero or smaller than zero, there is actually a lack of inlet pressure.

As a result, it is not possible in that case to increase the energy efficiency of the piping network by simply decreasing the inlet pressure with a certain amount.

In that case a rearrangement of the piping network is the only further possibility for improvement or optimization of the piping network.

An advantage of such a method in accordance with the invention is that the process of deciding involves a comparison between potential financial savings due to an increase in energy efficiency caused by a rearrangement of the piping network with costs for rearranging the piping network.

The comparison is done by means of some automatically executed computational calculations and in that way, it is easily decided whether or not by a rearrangement of the piping network the efficiency of it can still be increased in a manner which is sound from an economic point of view.

In a preferred embodiment of a method according to the invention the evaluation in step i comprises the following steps of:
j.—generating one or more theoretical piping networks (TPN) wherein a rearrangement or combination of rearrangements of the piping network has been applied;
k.—calculating potential financial savings (PFS) for each possible rearrangement or combination of rearrangements of the piping network; and,
l.—keeping the highest potential financial savings (PFS) and the corresponding rearrangement or combination of rearrangements of the piping network.

A further aspect of a possible method in accordance with the invention is that step k of calculating potential financial savings for each possible rearrangement or combination of rearrangements of the piping network comprises the step m of the of a theoretical calculation minimum overpressure which theoretically hypothetically occurs in the corresponding theoretical piping network wherein the concerned rearrangement or combination of rearrangements of the piping network has been applied and this at the pipe outlet where the smallest minimal overpressure over time is measured in reality.

Still another aspect of a possible method in accordance with the invention is that the calculation of potential financial savings for a particular possible rearrangement or combination of rearrangements of the piping network in step k comprises the step n of deciding that the concerned rearrangement or combination of rearrangements of the piping network does not generate potential financial savings, when the concerned theoretical minimum overpressure is zero or smaller than zero and, when the theoretical minimum overpressure is greater than zero, comprises the step o of calculating the potential financial savings when in the concerned theoretical piping network the initial inlet pressure is decreased with an amount which is equal to or slightly larger or slightly smaller than the smallest of the theoretical minimum overpressure and the second smallest minimal overpressure occurring in the piping network during the measuring period.

In a possible method in accordance with the invention the steps m, n and o are repeated multiple times for different possible rearrangements or combinations of rearrangements of the piping network resulting in different financial savings and in step l of the method the rearrangement or combination of rearrangements which is related to the highest potential financial savings is selected and stored.

In still another possible method in accordance with the invention the potential financial savings or the highest potential financial savings together with the corresponding rearrangement or combination of rearrangements of the piping network are visualized to a user or an operator.

Preferably, a method in accordance with the invention is executed with electronic means and/or is a computer-implemented method.

A method according to the invention is typically also suitable for being implemented as a computer program which comprises instructions which, when the program is executed by a computer, cause the computer to carry out the method.

An advantage of the afore-mentioned embodiments of a method in accordance with the invention is that the usefulness is automatically evaluated of possible rearrangements of the piping network for as far as the improvement or optimization of the efficiency of the complete system for pressurized fluid which comprises the piping network and the resulting potential financial savings are concerned.

Other methods in accordance with the invention will be discussed in more detail in the next section of this text.

The present invention also concerns a data processing apparatus or computer comprising a processor adapted to perform the steps of the method of the invention.

Furthermore, the present invention is also regarding a compressor, the compressor comprising a data processing apparatus or computer of the invention.

Finally, the present invention is also concerning a computer program comprising instructions which, when the program is executed by a computer, cause the computer to carry out a method in accordance with the invention.

### BRIEF DESCRIPTION OF THE DRAWINGS

The invention will further be illustrated with references to the drawings, wherein:

FIG. 1 is a schematic drawing of a system for pressurized fluid which comprises a piping network on which a method in accordance with the invention can be applied for improvement or optimization of the energy efficiency of the system for pressurized fluid;

FIG. 2 illustrates a part of the piping network of FIG. 1, wherein a possible appliance at a pipe outlet of the piping network has been symbolized more in detail;

FIG. 3 illustrates in the form of a flowchart a possible method in accordance with the present invention for optimization or improvement of the efficiency of a system for pressurized fluid which comprises a pressurized piping network which is subjected to a varying load at some pipe outlets;

FIG. 4 illustrates in the form of a flowchart in more detail the steps which are involved in the execution of step i represented in FIG. 3;

FIG. 5 illustrates in the form of a flowchart in more detail the steps which are involved in the execution of step l represented in FIG. 4;

FIG. 6 illustrates in the form of a flowchart in more detail the steps which are involved in the execution of step m in FIG. 4;

FIG. 7 illustrates a first situation with a typical fluctuation of pressure measured at two pipe outlets of a piping network, in particular before an optimization or improvement of the efficiency of the system for pressurized fluid with a method according to the present invention is realized;

FIG. 8 illustrates in a similar way as in FIG. 7 the fluctuation of pressure at the two pipe outlets of the piping network after the inlet pressure has been decreased and after an optimization or improvement of the efficiency of the system for pressurized fluid with a method according to the present invention is obtained;

FIG. 9 represents in a similar way as in FIG. 7 a second situation with another typical fluctuation of pressure measured at two pipe outlets of a piping network and this again before an optimization or improvement of the efficiency of the system for pressurized fluid is obtained with a method according to the present invention;

FIG. 10 illustrates in a similar way as in FIG. 9 the theoretically calculated changes of pressure to be expected at one of the two outlets when the piping network is rearranged, for example by increasing a diameter of a pipe of the piping network; and,

FIG. 11 depicts in a similar way as in FIGS. 9 and 10 the pressure measured at the two outlets after the rearrangement of the piping network has been implemented and the inlet pressure has been decreased and the efficiency of the system for pressurized fluid has been optimized or improved by means of a method in accordance with the invention.

### DETAILED DESCRIPTION OF EMBODIMENT(S)

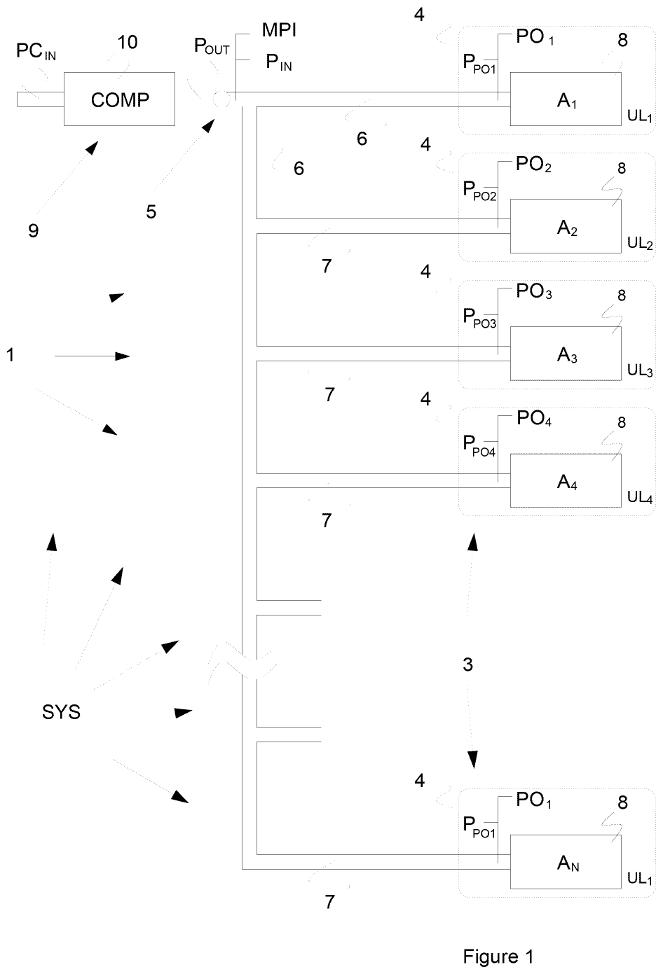

FIG. 1 illustrates a system for pressurized fluid SYS which comprises a piping network 1 which is provided with a main pipe inlet (MPI) 2 and multiple pipe outlets 3 (PO₁, PO₂, PO₃, . . . PO_{N}). In this case there are a number of N pipe outlets 3 in total.

The pipe outlets 3 are located at user locations 4 (UL₁, U₂, UL₃, . . . UL_{N}), which are spaced from one another and which are represented in FIG. 1 by means of a region surrounded by a dashed line. As explained in the introduction, the distance between the user locations 4 depends on the application and can be several meters or less to hundreds of meters and can even be one or more kilometers.

A main pipe piece 5 extends from the main pipe inlet 2. This main pipe piece 5 is branched into several pipe branches 6 and pipe subbranches 7.

Each pipe outlet 3 (PO₁, PO₂, PO₃, . . . PO_{N}) is connected to the main pipe inlet 2 (MPI) by means of a pipe formed by a combination of the main pipe piece 5 and a pipe branch 6 and possibly a pipe subbranch 7. In other configurations it is of course possible that still other subbranches are connected to a subbranch 7 and so on. The configuration of FIG. 1 is just an example.

User devices or appliances 8, which are indicated in FIG. 1 as A₁, A₂, A₃, . . . A_{N}, are provided at the user locations 4 and these user devices or appliances 8 are connected to the corresponding pipe outlet 3 of the concerned user location 4 with the intention of being supplied by means of the piping network 1 with pressurized fluid, typically pressurized air.

In the schematic drawing of FIG. 1 such an appliance 8 is represented by a square box, but in reality, such an appliance 8 can be any tool or device or combination of tools or devices that need(s) pressurized fluid.

For supplying pressurized fluid to the piping network 1 and through the piping network 1 to the appliances 8, at the main pipe inlet 2 of the piping network 1 fluid pressurized to an inlet pressure P_{IN} is provided by a source of pressurized fluid 9 of the system for pressurized fluid SYS.

This source of pressurized fluid 9 is typically a compressor 10 (COMP) of the system for pressurized fluid SYS, which is also the case in the embodiment of FIG. 1, but other sources could be used for this purpose.

The compressor 10 takes in uncompressed air at its inlet, typically at a pressure PC_{IN} Which is the atmospheric pressure.

In the compressor 10 this air is compressed, and the compressed air is discharged at the outlet of the compressor 10 at a higher pressure PC_{OUT}.

At the pipe outlets 3, the piping network 1 is subjected to a varying load due to varying demands of pressurized fluid during operation of the user devices or appliances 8, which are connected to the piping outlets 3 at the user locations 4.

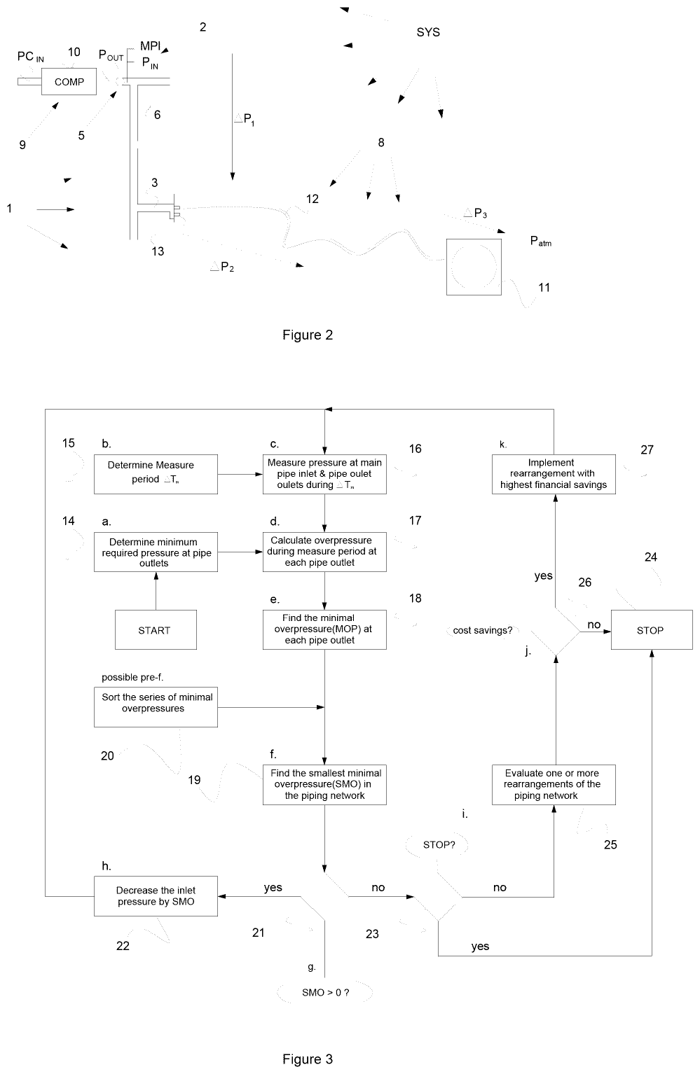

FIG. 2 illustrates more in detail the situation for one of the pipe outlets 3.

An appliance 8 is in this case represented by a pneumatically driven mechanical tool 11 that is connected by means of a flexible pneumatic hose 12 to the pipe outlet 3 of the piping network 1, from which pipe outlet 3 pressurized fluid is taken during operation with the mechanical tool 11.

At the same pipe outlet 3 there is also a valve 13 which is not connected to any appliance 8.

For purposes of clarity, let us now consider two situations.

In a first situation the mechanical tool 11 is not used and the valve 13 is opened without any load being applied at the valve 13.

In that case the pressure at or near to the pipe outlet 3 (P_{POi}) is the atmospheric pressure Pₐₜₘ and the part of the piping network 1 is exposed to a pressure difference P_{IN}−Pₐₜₘ which is the difference between a high pressure P_{IN}, Which is equal to the outlet pressure PC_{OUT} of the compressor 10, and the atmospheric pressure Pₐₜₘ. By opening the valve 13 the fluid will accelerate in the pipe branches 6 and subbranches 7 to the pipe outlet 3 where it attains a certain velocity. As soon as the pressure ratio between the pressure P_{IN} at the main pipe inlet 2 and the atmospheric pressure Pₐₜₘ is big enough, i.e., when this ratio is higher than a critical minimum pressure ratio (which is for air around 1, 89), the fluid starts to flow in so-called choked flow regime. In that case the fluid flows out of the concerned pipe outlet 3 at a maximum velocity which is equal to the speed of sound.

The total pressure drop ΔPₜₒₜ over the concerned pipe part is in this case equal to ΔP₁, which is the difference between P_{IN} and atmospheric pressure Pₐₜₘ or a certain critical pressure P_{c} in the case of choked flow. (ΔPₜₒₜ=P_{IN}−Pₐₜₘ or ΔPₜₒₜ=P_{IN}−P_{c}).

This pressure drop ΔP₁ over the concerned pipe part comprises a kinetic component, which is due to an increase of the velocity of the fluid in the piping network 1, as well as a pressure component which is caused by friction losses in the part of the piping network 2 that connects the main pipe inlet 2 with the concerned pipe outlet 3. It appears that in practice the kinetic component is negligible.

When the flow in this piping network 1 is supposed to be turbulent flow, this friction loss is more or less proportional with the square of the fluid velocity (v²) and more or less inversely proportional with the diameter of the concerned pipe.

A lot of other factors play a role, as has been explained in the introduction.

Nevertheless, one can understand that in this case the pressure must drop from the inlet pressure P_{IN} to the atmospheric pressure Pₐₜₘ or a critical pressure P_{c} in the case of choked flow. The pressurized fluid, such as pressurized air, reaches a relatively high velocity or even a velocity equal to the sound of speed, and high friction losses are involved. In this first case the following is valid: ΔP₁=ΔPₜₒₜ=P_{IN}−Pₐₜₘ or ΔP₁=ΔPₜₒₜ=P_{IN}−P_{c}.

In the second situation valve 13 is closed and the mechanical tool 11 is used. In that case there is a pressure drop ΔP₃ over the mechanical tool 11, since pressurized fluid is used to do some mechanical work with the tool 11.

Furthermore, there is a pressure drop ΔP₂ in the flexible hose 12 which connects the mechanical tool 11 to the pipe outlet 3.

It is clear that in this case the total pressure drop ΔPₜₒₜ from the inlet pressure P_{IN} at the main pipe inlet 2 of the piping network 1 to the atmospheric pressure Pₐₜₘ at the outlet of the mechanical tool 11 is composed by three components: a first pressure drop ΔP₁ due to acceleration of the fluid and friction losses in the piping network 1, a second pressure drop ΔP₂ due to acceleration of the fluid and friction losses in the flexible hose 12 and a third pressure drop ΔP₃ which is the useful pressure for doing the mechanical work with the tool 11 (ΔPₜₒₜ=ΔP₁+ΔP₂+ΔP₃).

In this case the pressure P_{POi} at the pipe outlet 3 of the piping network 1 is somewhere between the inlet pressure P_{IN} and the atmospheric pressure Pₐₜₘ and depends on the characteristics of the flexible pneumatic hose 12 and pneumatic mechanical tool 11 and the use of that tool 11.

When the mechanical tool 11 or any other mechanical tool connected to the piping network 1 is not yet used and no pressurized fluid is flowing through the piping network 1, the pressure P_{POi} at the pipe outlet 3 of the piping network 1 is more or less equal to the inlet pressure P_{IN} at the main pipe inlet 2.

However, as soon as the mechanical tool 11 or any other mechanical tool connected to the network is being used, some pressurized fluid is flowing through the piping network 1 and also friction losses in the piping network 1 will occur.

Furthermore, as soon as the mechanical tool 11 is being used, some pressurized fluid is also flowing in the flexible hose 12 causing extra friction losses and work is done with the mechanical tool 11.

So, the pressure P_{POi} at the pipe outlet 3 will drop a bit and the more pressurized fluid is consumed by the mechanical tool 11, the more this pressure P_{POi} will drop.

It is clear that also consumption of pressurized fluid at other pipe outlets 3 of the piping network 1 than the pipe outlet 3 to which the mechanical tool 11 is connected have an influence on the pressure P_{POi} at that pipe outlet 3.

One can easily understand that at least some minimum pressure P_{POi}^{req} is always required at the pipe outlet 3 in order to provide sufficient pressurized fluid, when the mechanical tool 11 is used at its maximum capacity.

Normally, the piping network 1 is designed in such a way that the pressure drop ΔP₁ between the main pipe inlet 2 and the concerned pipe outlet 3 is limited, so that at the pipe outlet 3 always the required minimum pressure P_{POi}^{req} is available.

In practice however, the piping network 1 can be quite extended with many branches 6 and subbranches 7, with distances between the main pipe inlet 2 and the concerned pipe outlets 3 varying a lot, and with appliances 8 having all kinds of power needs which also can vary a lot in time.

From the above explanations, one understands that it is far from obvious to factor all the requirements and possibly changing demands already at the design stage.

A minimum required pressure P_{POi}^{req} at every pipe outlet 3 can be ensured by setting the pressure P_{IN} at the main pipe inlet 2 at a sufficiently high level.

A disadvantage of such a way of designing the piping network 1 is that the pressure P_{IN} at the main pipe inlet 2 is usually set at a level which is unnecessarily high, since appliances 8 are in practice never or almost never used simultaneously at their maximum capacity.

The higher the pressure P_{IN} at the main pipe inlet 2, the higher the pressure PC_{OUT} at the outlet pipe of the compressor 10, the more energy is consumed by the compressor 10 and the higher the cost related to energy consumption will be.

The present invention provides a method for improving or optimizing the efficiency of such a system for pressurized fluid SYS with a piping network 1 under a varying load at the pipe outlets 3 and such a method in accordance with the invention takes into account the real loads experienced at the pipe outlets 3 of the piping network 1 during a typical duty cycle and the method ensures that the pressure P_{IN} at the main pipe inlet 2 of the piping network 1 is not set unnecessarily high.

Such a method in accordance with the invention will now be described more in detail.

FIG. 3 represents a flow chart describing the steps involved in a method in accordance with the invention.

A first step a) of the method is represented in box 14 and in this first step of the method for one or more pipe outlets 3 the minimum pressure P_{POi}^{req} which is required at any time at the corresponding user location ULᵢ is determined, so that operations at that user location ULᵢ can take place uninterruptedly.

In another step b) of such a method according to the invention, which is represented in box 15 of FIG. 3, a measuring period ΔTₘ corresponding to a typical duty cycle of the piping network 1 is determined, during which pressure P_{IN} at the main pipe inlet 2 and the pressures P_{PO1}, P_{PO2}, P_{PO3}, . . . , P_{PON} at the concerned pipe outlets 3 will be measured.

In the next step c) of a method in accordance with the invention, which is described in box 16 of FIG. 3, the pressure P_{IN} at the main pipe inlet 2 and the pressures P_{PO1}, P_{PO2}, P_{PO3}, . . . , P_{PON} at the concerned pipe outlets 3 are measured during the measuring period ΔTₘ.

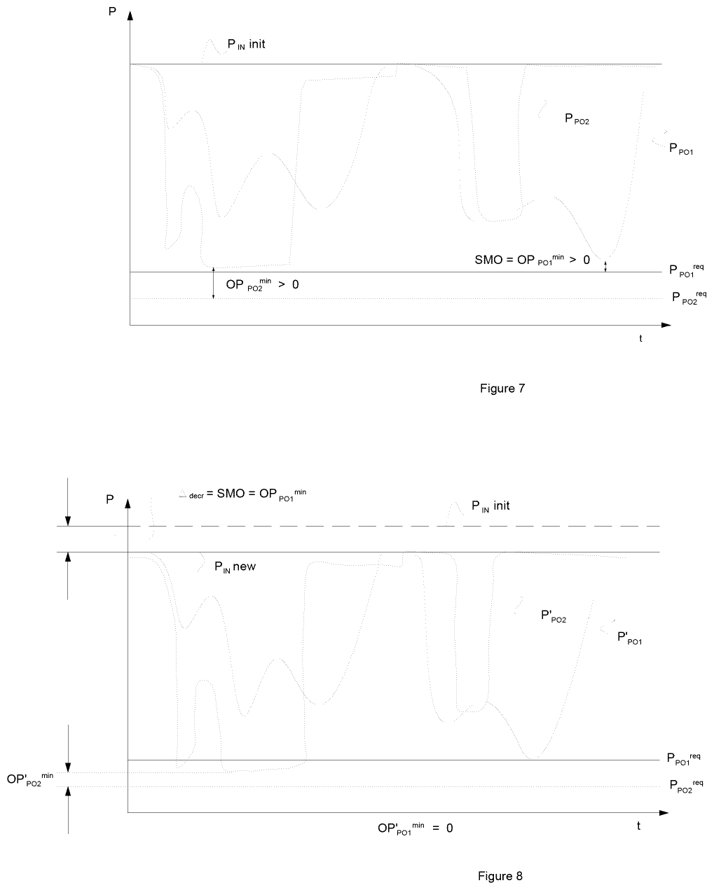

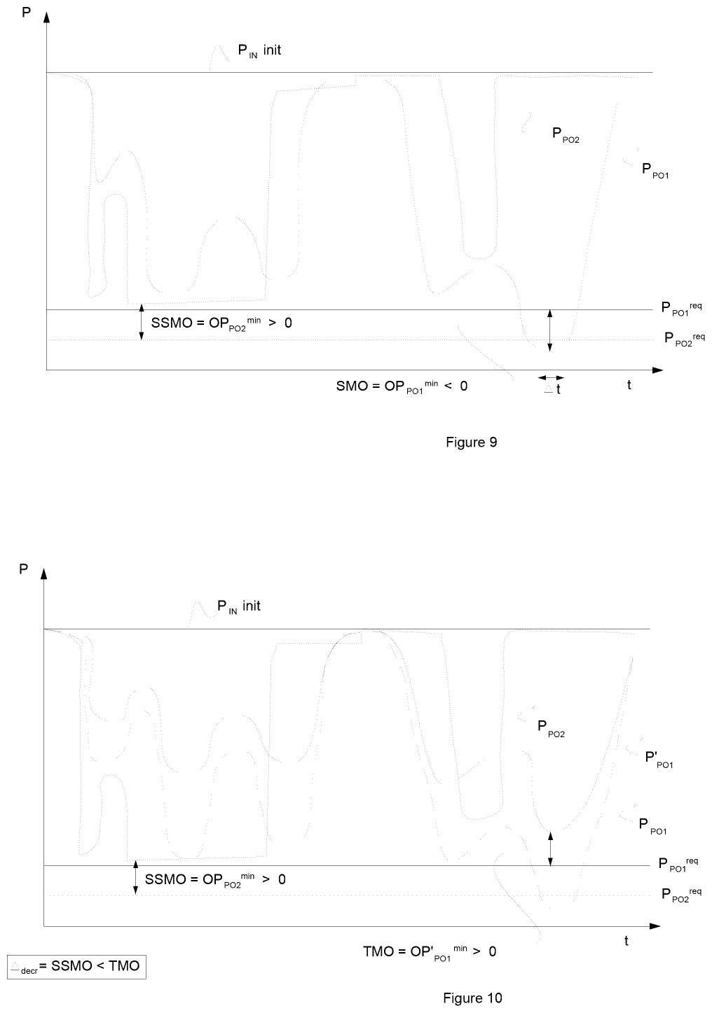

Examples of such a measurement of pressures P_{PO1} and P_{PO2} during the measuring period ΔTₘ are represented in FIGS. 7 and 9 for two pipe outlets 3 of the piping network 1, respectively indicated with index 1 and index 2.

In a preferred method according to the invention, the pressure P_{IN} at the main pipe inlet 2 and the pressures P_{PO1}, P_{PO2}, P_{PO3}, . . . , P_{PON} at the concerned pipe outlets 3 are measured in a synchronous way during the measuring period ΔTₘ in step c) of the method.

This is preferred since it is in that manner that the total load to which the piping network 1 is subjected can be known at any moment in time in the most accurate way.

The fluctuation of the pressures P_{IN}, P_{PO1}, P_{PO2}, P_{PO3}, . . . , P_{PON} during the measuring period ΔTₘ can for example be determined in an analogue manner.

However, with the techniques of today in a preferred method according to the invention the measurement of pressures P_{IN}, P_{PO1}, P_{PO2}, P_{PO3}, . . . , P_{PON} during the measuring period ΔTₘ in step c) of the method is a digital pressure measurement which is executed simultaneously at the different concerned pipe outlets 3 and this at discrete points in time t₁, t₂, t₃, . . . during the measuring period ΔTₘ.

The discrete points in time t₁, t₂, t₃, . . . should be near to one another compared relatively to the speed by which changes in load at the pipe outlets 3 of the piping network 1 occur, so that no situations with high load are missed during measurement of the pressures P_{IN}, P_{PO1}, P_{PO2}, P_{PO3}, . . . , P_{PON}.

In a next step d) of a method in accordance with the invention, which is illustrated by box 17 in FIG. 3, the difference during the measuring period ΔTₘ between the usually varying pressures P_{PO1}, P_{PO2}, P_{PO3}, . . . P_{PON} at each concerned pipe outlet 3 and the corresponding minimum pressures P_{PO1}^{req}, P_{PO2}^{req}, P_{PO3}^{req}, . . . , P_{PON}^{req}, which are required at any time at the corresponding user location UL₁, UL₂, UL₃, . . . , UL_{N} are calculated, so to find the corresponding overpressures OP_{PO1}, OP_{PO2}, OP_{PO3}, . . . , OP_{PON} at the concerned pipe outlet 3 which are usually also varying during the measuring period ΔTₘ.

The term overpressure should be understood correctly. In reality, such an overpressure OP_{PO1}, OP_{PO2}, OP_{PO3}, . . . or OP_{PON} Can be positive or negative since it is the result of a subtraction between a pressure P_{PO1}, P_{PO2}, P_{PO3}, . . . or P_{PON} measured at a pipe outlet 3 and the corresponding minimum required pressures P_{PO1}^{req}, P_{PO2}^{req}, P_{PO3}^{req}, . . . or P_{PON}^{req} at that pipe outlet 3.

This means that in reality such an overpressure OP_{PO1}, OP_{PO2}, OP_{PO3}, . . . or OP_{PON} can actually be a “negative pressure” in the case the calculated result is negative.

In the example illustrated in FIG. 7 there are only positive overpressures OP_{PO1} and OP_{PO2} during the measuring period ΔTₘ, while in the example, which is illustrated in FIG. 9, the pressure P_{PO1} at pipe outlet PO₁ is plunging under the minimum required pressure P_{PO1}^{req} at that pipe outlet PO₁ during a certain time interval Δt within the measuring period ΔTₘ, so that the overpressure OP_{PO1} at the pipe outlet PO₁ is temporarily negative during that time interval Δt. The fact that during the time interval Δt the pressure P_{PO1} at pipe outlet PO₁ is lower than the minimum required pressure P_{PO1}^{req} at that pipe outlet PO₁ can be considered as being an anomaly of the operations.

In a next step e) of a method in accordance with the invention, which is represented by box 18 in FIG. 3, for each concerned pipe outlet 3 (PO₁, PO₂, PO₃, . . . PO_{N}) the minimal overpressures OP_{PO1}^{min}, OP_{PO2}^{min}, OP_{PO3}^{min}, . . . and OP_{PON}^{min} occurring during the measuring period ΔTₘ are sought so to obtain a series of minimal overpressures OP_{PO1}^{min}, OP_{PO2}^{min}, OP_{PO3}^{min}, . . . and OP_{PON}^{min} composed of the minimal overpressures of each concerned pipe outlet 3 (PO₁, PO₂, PO₃, . . . PO_{N}).

In a preferred method according to the invention wherein step c) is based on synchronous, discrete digital measurements of pressures, the calculation and finding in steps d) and e) of the method are executed on this group of discrete digital measurements.

A next step f) of a preferred method in accordance with the invention, which is represented by box 19 in FIG. 3, consists of finding the smallest minimum overpressure SMO occurring in the piping network 1 during the measuring period ΔTₘ.

This is the overpressure of one of the pipe outlets 3 in the series of minimum overpressures OP_{PO1}^{min}, OP_{PO2}^{min}, OP_{PO3}^{min}, . . . or OP_{PON}^{min} of all the pipe outlets 3 which has the lowest value.

In the example of FIG. 7 this SMO is the minimum overpressure OP_{PO1}^{min} of pipe outlet PO₁, since this minimum overpressure OP_{PO1}^{min} is the smallest minimum overpressure in the series of minimum overpressures consisting of only OP_{PO1}^{min} and OP_{PO2}^{min}.

In the example of FIG. 9 this smallest minimum overpressure SMO is also the minimum overpressure OP_{PO1}^{min} of pipe outlet PO₁.

In this example of FIG. 9, the absolute value of the minimum overpressure OP_{PO1}^{min} occurring at pipe outlet PO₁ is maybe not smaller than the absolute value of the minimum overpressure OP_{PO2}^{min} occurring at pipe outlet PO₂, but in this case the minimum overpressure OP_{PO1}^{min} has a negative value and is therefore smaller than the minimum overpressure OP_{PO2}^{min}, which is a positive minimum overpressure OP_{PO2}^{min}.

So, the smallest minimum overpressure SMO is in this example again OP_{PO1}^{min}.

In a preferred method according to the invention the step f) is possibly preceded by a step pre-f), represented by box 20 in FIG. 3, wherein the series of minimum overpressures OP_{PO1}^{min}, OP_{PO2}^{min}, OP_{PO3}^{min}, . . . or OP_{PON}^{min} of all the pipe outlets 3 is sorted according to increasing from the size smallest minimal overpressure SMO to the biggest minimal overpressure.

In that case step f) of the method consists of simply taking the first value in the sorted series of minimum overpressures as the smallest minimum overpressure SMO occurring at a concerned pipe outlet 3 during the measuring period ΔTₘ.

In a next step g) of a method in accordance with the invention, which is represented by rhombus shape 21 in FIG. 3, an evaluation is made whether the smallest minimal overpressure SMO occurring in the piping network 1 during the measuring period ΔTₘ, is bigger than zero or not.

When the smallest minimal overpressure SMO is bigger than zero, the step h) of the method is executed, which is represented by box 22 in FIG. 3.

In this step h) it is proposed to decrease the initial inlet pressure P_{IN}^{init} of the piping network 1 with an amount which is equal to or slightly larger or slightly smaller than the smallest minimal overpressure SMO occurring in the piping network 1 during the measuring period ΔTₘ, so that the inlet pressure P_{IN} at the main pipe inlet 2, which is the same as the compressor outlet pressure PC_{OUT}, is set at a new inlet pressure P_{IN}^{new}, which is the initial inlet pressure P_{IN}^{init} from which the smallest minimal overpressure SMO or a slightly larger or slightly smaller pressure is subtracted (P_{IN}^{new}=P_{IN}^{init}−SMO). The reason why a slightly smaller pressure can possibly be subtracted from the initial inlet pressure P_{IN}^{init}, is to preserve a small safety margin in order to ensure that the pressure P_{POi} at the concerned pipe outlet POᵢ, after having decreased the initial inlet pressure P_{IN}^{init}, is kept at any time above the corresponding minimum required pressure P_{POi}^{req} at that pipe outlet POᵢ. In the event that one does not need a safety margin, one can also subtract a slightly larger pressure from the initial inlet pressure P_{IN}^{init} so that one can maximize the energy yield at the expense of always having the minimum required pressure P_{POi}^{req} at that pipe outlet POᵢ available.

As explained before, in the case of FIG. 7, the smallest minimum overpressure SMO occurring in the piping network 1 during the measuring period ΔTₘ is indeed bigger than zero, and, as a consequence, in this example, in step h) a decrease of the initial inlet pressure P_{IN}^{init} with an amount equal to the occurring smallest minimum overpressure SMO is proposed. In this example, the smallest minimum overpressure SMO is the minimum overpressure OP_{PO1}^{min} measured at the first pipe outlet OP₁.

The situation after application of the proposed diminution of the initial inlet pressure P_{IN}^{init} into a new inlet pressure P_{IN}^{new} is illustrated in FIG. 8.

It is clear that by such a reduction of the inlet pressure P_{IN} at the main pipe inlet 2, or what is the same, a reduction of the outlet pressure PC_{OUT} at the outlet of the compressor 10, the energy efficiency of the system for pressurized fluid, including the compressor 10, the piping network 1, . . . is improved or optimized.

Less energy is consumed when the compressor 10 is working at a lower outlet pressure PC_{OUT}, which results in lower operation costs as explained in the introduction.

FIG. 8 also illustrates that the pressures P′_{PO1} and P′_{PO2} respectively at pipe outlets PO₁ and PO₂ after application of the new inlet pressure P_{IN}^{new} are also reduced with approximately the same amount corresponding to the smallest minimum overpressure SMO in the piping network 1, compared to the original pressures P_{PO1} and P_{PO2} respectively at pipe outlets PO₁ and PO₂ when the initial inlet pressure P_{IN}^{init} was still applied.

Therefore, as can be seen in FIG. 8, after application of the new inlet pressure P_{IN}^{new}, the overpressures OP′_{PO1} and OP′_{PO2} during operation are always positive or equal to zero, or, what is the same, there is never a lack of pressure P′_{PO1} and P′_{PO2} at any of the pipe outlets PO₁ and PO₂, since these pressures P′_{PO1} and P′_{PO2} are always above the corresponding required minimum pressures P_{PO1}^{req} and P_{PO2}^{req}.

This proves that after optimization or improvement of the efficiency of the system for pressurized fluid SYS, the operations executed with the appliances A1, A2, etc. . . executed at the corresponding pipe outlets PO₁, PO₂, . . . of the piping network 1 can still take place uninterruptedly.

When in step g) of the method it is determined that the smallest minimal overpressure SMO is zero or lower than zero, the step i) of the method is executed.

Step i) can simply consist of making the decision that no further efforts for improving or optimizing the efficiency of the system for pressurized fluid SYS are made, for example when there is no intention to rearrange the piping network 1 by increasing a diameter of pipes in the piping network 1 or inserting a pressure vessel in the piping network 1. This evaluation is represented by rhombus shape 23 in FIG. 3 and, if no further efforts are made, the method is terminated, which is indicated by box 24 in FIG. 3.

As an alternative or additionally, when the smallest minimal overpressure SMO is zero or lower than zero, in step i) of the method it could be decided to counter the apparently existing anomaly or lack of pressure at the concerned pipe outlet 3 by increasing the initial pressure P_{IN}^{init} with an amount equal to or slightly lower or slightly higher than (the absolute value of) the smallest minimal overpressure SMO. In that case, the inlet pressure P_{IN}^{init} is set at a new inlet pressure P_{IN}^{new} which is sufficiently high to avoid the occurrence of any anomaly at the pipe outlets 3 during operation, due to lack of pressure at a concerned pipe outlet 3. A disadvantage of such a practice is of course that the energy consumption or efficiency of the system for pressurized fluid SYS is not improved or optimized, but on the contrary that the energy consumption is increased, or the efficiency decreased.

However, in a more interesting implementation of a method in accordance with the invention, in step i) an evaluation is made of one or more possible rearrangements to the piping network (1) for increasing the energy efficiency of the piping network (1).

In a preferred method according to the invention the execution of step i, in the case the smallest minimal overpressure SMO is zero or smaller than zero, comprises an evaluation which involves a calculation of potential financial savings due to an increase in energy efficiency caused by a rearrangement of the piping network 1 versus costs for rearranging the piping network 1.

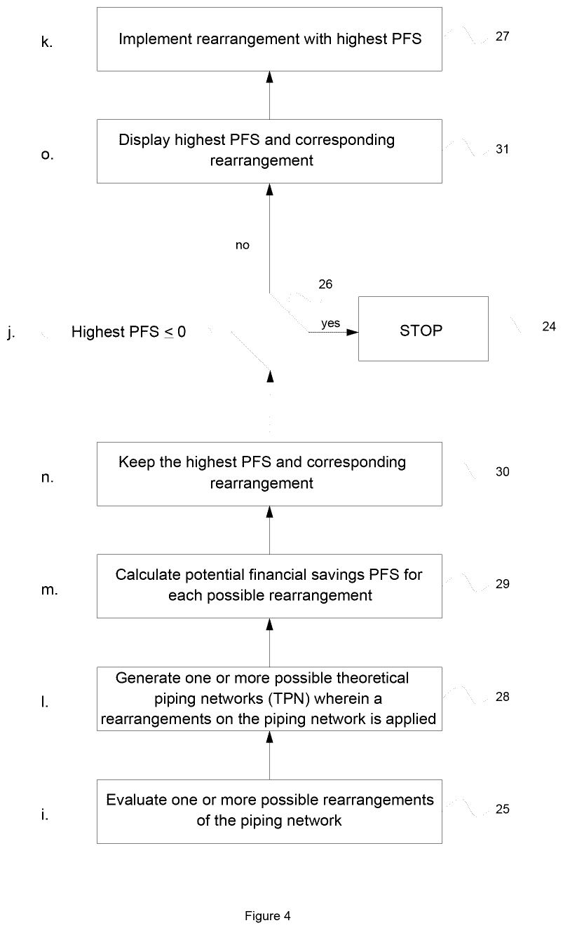

This step i) of a method in accordance with the invention is represented by box 25 in FIG. 3, but this step i) comprises many other underlying or subsequent actions, represented in FIGS. 4 to 6, wherein an evaluation is made of possible rearrangements to the piping network 1 for reducing the energy consumption or increasing the energy efficiency of the compressed air system or system for pressurized fluid SYS.

The evaluation of possible rearrangements of the piping network 1 comprises the calculation of potential financial savings PFS and when there are possible financial savings, in additional steps j) and k) a decision can be made to implement the rearrangement which corresponds to the highest potential financial savings. These steps j) and k) are illustrated by rhombus shape 26 and box 27 in FIG. 3.

After implementation of the concerned rearrangement of the piping network 1, steps c to i of the method are possibly again executed in order to further improve or optimize the efficiency of the system for pressurized fluid SYS.

Obviously, the method is preferably aborted, if from the evaluation of possible rearrangements of the piping network 1 it is concluded in step j) that no financial saving can be obtained. (See rhombus shape 25 in the case of “no”.)

A concerned example is illustrated in FIG. 9.

Indeed, the smallest minimal overpressure SMO occurring in the piping network 1 is in that case strictly lower than zero in the time interval Δt at the first pipe outlet PO₁ and thus is the pressure P_{PO1} measured at the corresponding pipe outlet PO₁ in that time interval Δt lower than the minimum pressure P_{PO1}^{req} required at that pipe outlet PO₁.

This means that the operations at the first user location UL₁ could probably not be performed as required during the afore-mentioned time interval Δt due to a lack of sufficiently pressurized fluid.

Obviously, in such a case, a reduction of the inlet pressure P_{IN} at the main pipe inlet 2 of the piping network 1 is not an option and other rearrangements of the piping network 1 should therefore be considered or the method could be aborted.

FIG. 4 illustrates more in detail possible steps for executing the step i) for evaluating one or more rearrangements of the piping network 1, represented in box 25 of FIGS. 3 and 4, until a possible implementation in step k) of such a rearrangement when such an implementation generates financial savings, which step k) is illustrated in box 27 of FIGS. 3 and 4.

As represented in FIG. 4, in a preferred method according to the invention the step i of evaluating one or more possible rearrangements of the piping network 1 comprises the following steps of:
l.—generating one or more theoretical piping networks TPN wherein a rearrangement or combination of rearrangements of the piping network 1 has been applied, which is represented in box 28 of the flow chart of FIG. 4;
m.—calculating potential financial savings PFS for each possible rearrangement or combination of rearrangements of the piping network 1, which is represented in box 29 of the flow chart of FIG. 4; and,
n.—keeping the highest potential financial savings PFS and the corresponding rearrangement or combination of rearrangements of the piping network 1, which is represented in box 30 of the flow chart of FIG. 4.

After having executed these different steps l, m and n for the generated rearrangements to be evaluated, the highest all potential financial savings PFS are known and when there are no potential financial savings found (see rhombus shape 26, representing step j, case of “yes”) the method should be aborted (box 24 of FIGS. 3 and 4).

This could for example be the case when the implementation of the proposed rearrangements is too costly and cannot be compensated by the energy savings due to an increased efficiency by rearranging the piping network 1.

However, in the case there are potential financial savings PSF, it can be interesting to implement the rearrangement with the highest PFS in step k.

In order to give an operator or user the opportunity to decide about such an implementation of a rearrangement of the piping network 1, the rearrangement and accompanying highest PFS can be displayed for example on a screen of a computer in an additional step o. This is illustrated in box 31 of FIG. 4.

The step m of calculating potential financial savings PFS for each possible rearrangement or combination of rearrangements of the piping network can for example comprise calculations or estimations of a kind explained hereafter. If a diameter d₁ of a pipe piece in the piping network 1 is changed into a diameter d₂, the associated percentage of reduction of energy consumption can be calculated with the following formula:

wherein

$$\% {\dot{X}}_{el}^{reduction} = \frac{- ln [ 1 - \frac{Δ {p}_{1}}{{p}_{1}} ( 1 - \frac{{d}_{1}^{5}}{{d}_{2}^{5}} ) ]}{ln {p}_{1} - ln {p}_{atm}}$$

p₁=the initial discharge pressure over the concerned pipe piece;
Δp₁=the initial discharge pressure drop over the concerned pipe piece;

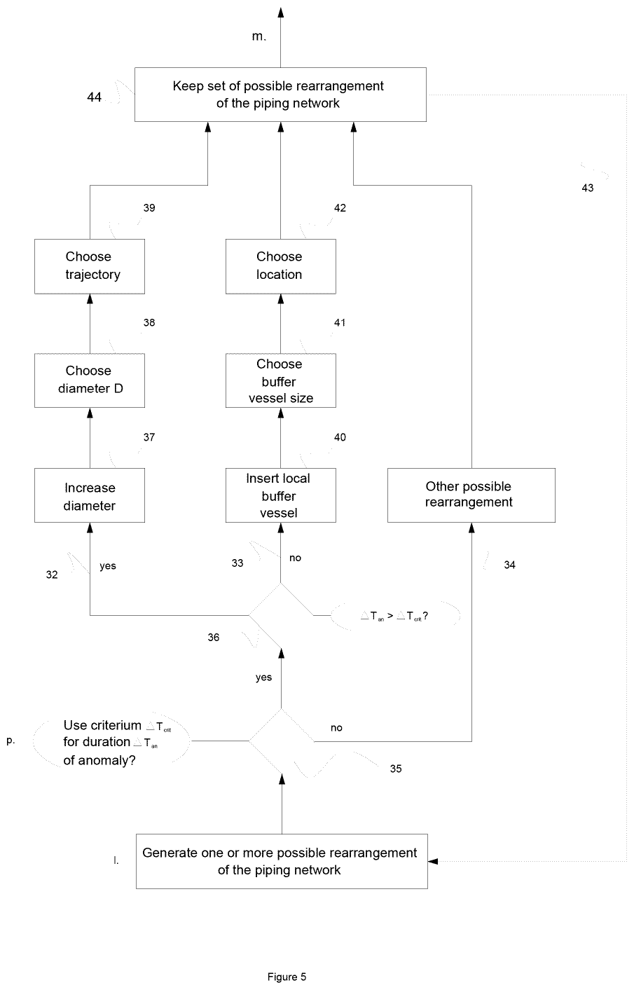

%\dot{X}ₑₗ^{reduction}=percentage reduction of electric exergy rate. In reduction FIG. 5 another flow chart represents in more detail a possible implementation of the step l) of a method of the invention wherein one or more theoretical piping networks TPN corresponding to possible rearrangements of the piping network 1 are generated.

It is of course not excluded from the invention to implement this step l) in a completely different way.

Preferably, according to the invention, executing step i of the method comprises an evaluation of the usefulness of a rearrangement of the piping network 1 which comprises an increase of the diameter D of one or more parts of the piping network 1 between the main pipe inlet 2 and the pipe outlet POᵢ where the smallest minimal overpressure SMO is measured, a corresponding theoretical piping network TPN being generated in step l of the method. This generation of such a TPN is represented by the route 32 in FIG. 5.

In another preferred method according to the invention the execution of step i of the method comprises an evaluation of the usefulness of a rearrangement of the piping network 1 which comprises an insertion of one or more local buffer vessels in a part of the piping network 1 between the main pipe inlet 2 and the pipe outlet POᵢ where the smallest minimal overpressure SMO is measured, a corresponding theoretical piping network TPN being generated in step l of the method. This generation of such a TPN is represented by the route 33 in FIG. 5.

Still other possible rearrangements of the piping network 1 and corresponding theoretical piping networks TPN can be generated, which is represented by route 34 in FIG. 5.

Sometimes it can be interesting to use an extra criterium for deciding whether or not a certain rearrangement of the piping network 1 should be evaluated. This is also the case in the flow chart of FIG. 5.

Such a criterium can be based on the period ΔTₐₙ wherein the anomaly occurs at the concerned pipe outlet POᵢ with zero or negative SMO.

This period ΔTₐₙ wherein the anomaly occurs, is the total duration, wherein the measured pressure P_{POi} at the concerned pipe outlet POᵢ is lower than the minimum pressure P_{POi}^{req} which is required at any time at that pipe outlet POᵢ and/or at the corresponding user location ULᵢ.

Such a criterium is not necessarily used in a method according to the invention and whether or not the criterium is used can for example be decided in an additional step p of the method, as is by way of example illustrated with the rhombus shape 35 in the flowchart of FIG. 5.

The used criterium can for example consist of an evaluation whether the period ΔTₐₙ wherein the anomaly occurs exceeds a certain pre-determined critical period of time ΔT_{crit} or not.

Such a possible use of an afore-mentioned criterium is by way of example illustrated with the rhombus shape 36 in the flowchart of FIG. 5.

For example, in a preferred method according to the invention, the evaluation in step i of the method of the usefulness of a rearrangement of the piping network 1 by increasing a diameter D of a part of the piping network 1 is only executed when the period ΔTₐₙ wherein the anomaly occurs, exceeds said pre-determined period of time ΔT_{crit}. This corresponds to the route 32 in FIG. 5.

This makes sense, since the effort of replacing a whole part of the piping network 1 by a part with a larger diameter D is only efficient if the anomaly is big enough or is taking place during a sufficiently long period ΔTₐₙ longer than the pre-determined period of time ΔT_{crit}. On the other hand, when the anomaly is occurring during a too long period ΔTₐₙ, the problem is not easily solved by inserting a local pressure vessel, since that would require a too big pressure vessel.

What's more, in such a preferred method according to the invention, the evaluation in step i of the usefulness of a rearrangement of the piping network 1 wherein a local buffer vessel is included in the piping network 1, is only executed when the period ΔTₐₙ wherein the anomaly occurs does not exceed said pre-determined period of time ΔT_{crit}. This corresponds to the route 33 in FIG. 5.

Also this kind of application of a criterium makes sense, for similar reasons. Indeed, the insertion of a local pressure vessel into the piping network 1 is only practically realizable when the duration of the anomaly ΔTₐₙ is not too big if at least its size should be kept within acceptable limits.

It is not excluded from the invention to incorporate the evaluation of the usefulness of still other rearrangements of the piping network 1 for increasing its efficiency, for example rearrangements which are a combination of the above-mentioned rearrangements by increasing a pipe diameter or including a local pressure vessel. Another possible rearrangement of the piping network 1 or system for pressurized fluid SYS could involve a relocation of the compressor 10 so to make the connection between the compressor 10 and the piping network 1 at another location, branch 6 or subbranch 7. As an alternative, an additional source of pressurized fluid or compressor 10 could be inserted into the piping network 1 and still other rearrangements of the piping network 1 could possibly considered. This corresponds to the route 34 in FIG. 5.

Such additional evaluations of other rearrangements of the piping network 1 can also be made dependent on still other criteria, but this is according to the invention also not necessarily the case.

A rearrangement of the piping network 1 wherein a diameter is increased (box 37 in FIG. 5) can for example comprise the additional steps of selecting a specific increased diameter D (box 38 in FIG. 5) and of choosing a pipe trajectory wherein this increased diameter D should be applied (box 39 in FIG. 5).

A rearrangement of the piping network 1 wherein a local buffer vessel is inserted (box 40 in FIG. 5) can for example comprise the additional steps of choosing a specific pressure vessel size (box 41 in FIG. 5) and of choosing a specific location where the pressure vessel should be inserted (box 42 in FIG. 5).

Several different possible theoretical piping networks TPN or rearrangements of the piping network 1 can possibly be generated by repeating the process (see route 43 in dashed line) and a set of generated rearrangements can be stored (see box 44 of FIG. 5).

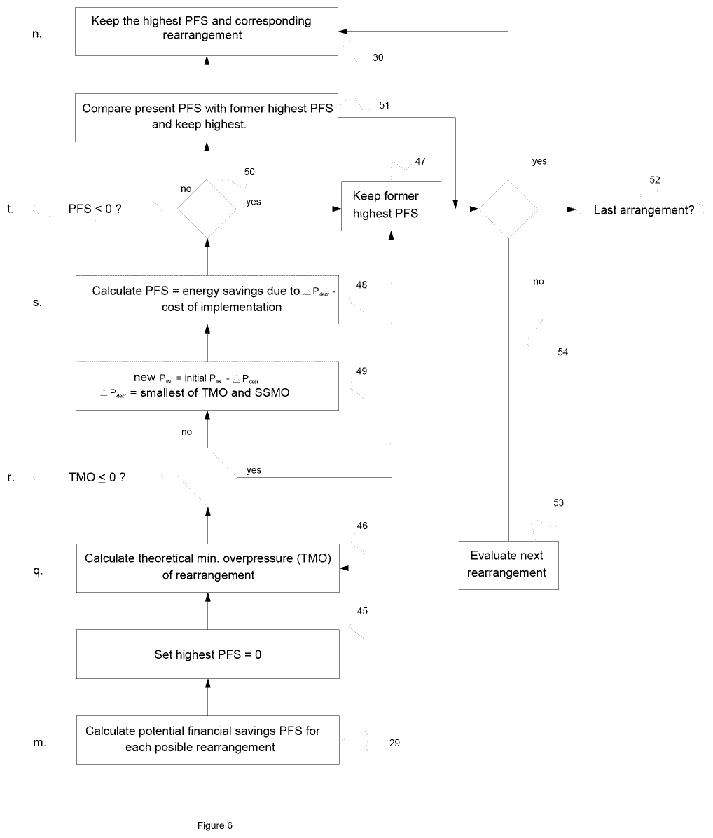

Finally, in FIG. 6 in a last flow chart a possible more detailed implementation of the step m), represented in FIG. 4, of calculating potential financial savings PFS for each possible rearrangement of the piping network 1 is illustrated.

Before the start of this calculation the highest potential financial savings are set to be zero. This is represented in box 45 of FIG. 6.

Furthermore, in the represented case, said step m of calculating potential financial savings PFS for each possible rearrangement or combination of rearrangements of the piping network 1 comprises the step q of the calculation of a theoretical minimum overpressure TMO. This illustrated with box 45 in FIG. 6.

This theoretical minimum overpressure TMO is the minimum overpressure that theoretically occurs over time in the corresponding theoretical piping network TPN wherein the concerned rearrangement or combination of rearrangements of the piping network 1 has been applied and this more particularly in the part of the piping network 1 between the main pipe inlet 2 and the pipe outlet POᵢ where the smallest minimal overpressure SMO is measured in the piping network 1.

The step m of calculating potential financial savings PFS for a particular possible rearrangement or combination of rearrangements of the piping network 1 preferably comprises also the step r of deciding that the concerned rearrangement or combination of rearrangements of the piping network 1 does not generate potential financial savings PFS, when the theoretical minimum overpressure TMO is zero or smaller than zero.

Actually, this means that with the concerned rearrangement or combination of rearrangements of the piping network 1 the smallest minimal overpressure SMO which was negative or zero (see step g of the method), would by implementation of the rearrangement still be negative or zero. The reason can for example be that an increased diameter D is chosen which is still not big enough in order to reduce the pressure drop between the main pipe inlet 2 and the concerned pipe outlet POᵢ. As a consequence, no financial savings can be realized with respect to the original situation. In the case the theoretical minimum overpressure TMO is “less” negative than the measured smallest minimal overpressure SMO, still a certain improvement of the efficiency of the system for pressurized fluid is obtained. Indeed, in that case, by applying the proposed rearrangement the increase of inlet pressure P_{IN} needed at the main pipe inlet 2 for avoiding lack of pressure or an anomaly occurring at any one of the pipe outlets POᵢ can be kept smaller than without applying the proposed rearrangement of the piping network 1. So, when it was decided to increase the inlet pressure P_{IN} for avoiding such an anomaly, it could from a financial point of view still make sense to apply the proposed rearrangement. When the theoretical minimum overpressure TMO is zero or smaller than zero, the concerned rearrangement does also not correspond to the rearrangement with highest potential financial savings, except in the case the highest potential financial savings are equal to zero. This is represented by box 47 of the flowchart of FIG. 6.

When he theoretical minimum overpressure TMO, calculated in step q, is greater than zero, the method comprises the additional step s, represented in box 48 of calculating the potential financial savings PSF when in the concerned theoretical piping network TPN the initial inlet pressure P_{IN}^{init} is decreased with an amount Δ_{decr} which is equal to the smallest of, on the one hand, the theoretical minimum overpressure TMO, and, on the other hand, the second smallest minimal overpressure SSM occurring in the piping network 1 during the measuring period ΔTₘ. This proposal of decreasing the initial inlet pressure P_{IN}^{init} with an amount Δ_{decr} is represented in box 49 of FIG. 6.

Actually, this step of the method of the invention can be compared with step f represented in box 19 in FIG. 3, wherein the smallest minimal overpressure SMO is sought based on measurements of pressure in the piping network 1. In this case, pressure measurements are combined with calculated pressures, but still a kind of smallest minimal overpressure SMO is sought, which is equal to the smallest of the second smallest minimal overpressure SSMO known from the measurements and the theoretical minimal overpressure TMO.

The second smallest minimal overpressure SSMO occurring in the piping network 1 during the measuring period ΔTₘ is the second item in the sorted series of minimum overpressures (see possible step pre-f).

The potential financial savings PFS can be calculated by subtracting the cost for implementing the rearrangement of the piping network 1 from the cost savings by having a more energy efficient theoretical piping network TPN, due to an inlet pressure which is decreased by Δ_{decr}. Of course, such an evaluation of costs and gains usually also involves the life expectancy or total expected operational period of the system for pressurized fluid.

The method comprises a further step t, represented by the rhombus shape 50 in the flowchart of FIG. 6, which consists of an evaluation whether the potential financial savings PFS calculated in step s are positive or negative. When the potential financial savings are negative, for example when the energy cost savings are too low or the implementation costs are too high, then obviously the proposed rearrangement is not suitable, so that the highest potential financial savings calculated up to now should not be changed (see again box 47 in FIG. 6).

If the financial savings PFS currently calculated in step s are positive, a comparison should be made with the highest potential financial savings calculated up to now and the highest of both should be kept as the currently calculated highest PFS. This is illustrated in box 51 of FIG. 6.

The steps q, r, s and t should be repeated for all the proposed or generated rearrangements until the last rearrangement is reached. This is represented by rhombus shape 52, box 53 and route 54 in FIG. 6.

Finally, if all the rearrangements have been evaluated, the rearrangement with highest PFS should be kept, which is step n in the method (see FIG. 4) and which is represented in box 30 in FIGS. 4 and 6.

After an evaluation of a single rearrangement or a set of rearrangements of the piping network 1 and its potential financial savings PFS, in a possible method according to the invention the proposed rearrangement or combination of rearrangements of the piping network 1 with highest financial savings can be implemented, which is represented by box 27 and rhombus shape 26 (case “yes”) in the flowchart of FIG. 3.

FIGS. 9 to 11 illustrate in a more practical way step i and the following steps of a method according to the invention in the case the calculated smallest minimum overpressure SMO is equal to or smaller than zero.

As explained, in FIG. 9 the pressure P_{PO1} at pipe outlet PO₁ plunges during a time interval Δt under the minimum pressure P_{PO1}^{req} required at that pipe outlet PO₁. The smallest minimum overpressure SMO is in this case negative and is represented by the minimum overpressure P_{PO1}^{min} occurring at pipe outlet PO₁. The time interval Δt is representing in this case the total duration ΔTₐₙ during which the anomaly is occurring, referred to before.

Of course, in other cases the pressure P_{PO1} could for example plunge multiple times under the minimum pressure P_{PO1}^{req} required during time intervals Δt₁, Δt₂, . . . and as a result another total duration ΔTₐₙ of the anomaly should be taken into consideration, which is the sum of those time intervals Δt₁, Δt₂, . . . .

As explained before, as a criterium for choosing a type of rearrangement of the piping system 1 that could be interesting for improving its efficiency, this total duration ΔTₐₙ of the anomaly could for example be compared to a pre-determined critical period ΔT_{crit}.

In the case the total duration ΔTₐₙ of the anomaly is bigger than said pre-determined critical period ΔT_{crit}, it could be decided to evaluate a rearrangement of the piping network 1, which consists of increasing the diameter D of a part of the pipes in the piping network 1. (see route 32 in FIG. 5)

In the other case wherein the total duration ΔTₐₙ of the anomaly is smaller than said pre-determined critical period ΔT_{crit}, it could be decided to evaluate a rearrangement of the piping network 1, which consists of inserting a local pressure vessel in the piping network 1. (see route 33 in FIG. 5)

The evaluation of the usefulness of the chosen rearrangement of the piping network 1 is illustrated in FIG. 10.

Based on the proposed rearrangement or combination of rearrangements of the piping network 1, a theoretical piping network TPN can be obtained wherein the concerned rearrangement or combination of rearrangements has been applied on the piping network 1.

In this theoretical piping network TPN a theoretical calculation can be made of the evolution of the pressure P′_{PO1} to be expected at the concerned pipe outlet, which is in this case pipe outlet PO₁, when the same kind of load is applied at that pipe outlet PO₁ as was the case during the measuring period ΔTₘ.

In FIG. 10 a possible result of such a calculated pressure evolution P′_{PO1} during a hypothetical measuring period ΔTₘ is drafted as a curve P′_{PO1}(t).

This theoretically calculated evolution of the pressure P′_{PO1} at the outlet PO₁ also results in another evolution of overpressure OP′_{PO1}(t) which would be theoretically present at the pipe outlet OP₁, when the rearrangement or combination of rearrangements is applied.

The minimum overpressure OP′_{PO1}^{min} of the evolution of overpressure OP′_{PO1}(t) occurring during the hypothetical measuring period ΔTₘ is indicated in FIG. 10 as OP′_{PO1}^{min} and represents the theoretical minimum overpressure TMO, which will be further used in the evaluation.

If this theoretical minimum overpressure TMO is equal to or smaller than zero, it is decided in step r of the method of the invention that the proposed rearrangement of the piping network 1 is not suitable for further improving the efficiency of the piping network 1.

Otherwise, when the theoretical minimum overpressure TMO is bigger than zero, it is compared with the second smallest minimum overpressure SSMO occurring in the piping network 1 and the smallest of the theoretical minimum overpressure TMO and the second smallest minimum overpressure SSMO is taken as a target pressure decrease Δ_{decr} by which the initial inlet pressure P_{IN}^{init} can be decreased for possibly improving the efficiency of the piping network 1.

In the example of FIG. 10, the second smallest minimum overpressure SSMO is the minimum overpressure P_{PO2}^{min} occurring at pipe outlet PO₂, since only two pipe outlets PO₁ and PO₂ are considered in this example, but in larger piping networks 1 this SSMO can be of course the minimum overpressure P_{POi}^{min} of any other pipe outlet POᵢ.

Furthermore, in the example of FIG. 10 the second smallest minimum overpressure SSMO is smaller than the theoretical minimum overpressure TMO, so that the proposed target pressure decrease Δ_{decr} for P_{IN} is the second smallest minimum overpressure SSMO.

When the calculation of potential financial savings PFS for the or each possible rearrangement by executing the steps m to n of the method represented in FIG. 6 results in a positive highest PFS, it can be decided that the corresponding rearrangement is applied.

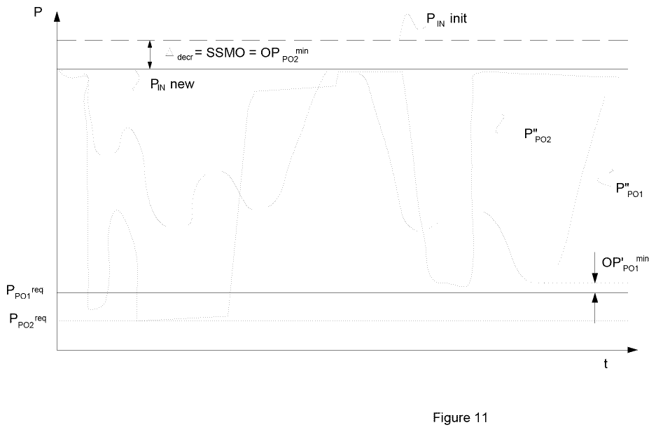

The possible resulting pressure evolutions P″_{PO1} and P″_{PO2} are illustrated in FIG. 11.

P″_{PO1} represents the pressure at PO₁ after the piping network 1 has been rearranged, for example by implementing an increased diameter D in the part of the piping network 1 between the main pipe inlet 2 and the concerned pipe outlet PO₁, and wherein the inlet pressure P_{IN}^{init} was decreased to a new inlet pressure P_{IN}^{new} by an amount Δ_{decr} which is equal to the SSMO and which is in this case the minimal overpressure P _{PO2}^{min} at the pipe outlet PO₂.

P″_{PO2} represents the pressure at PO₂ when of course the same new inlet pressure P_{IN}^{new} is applied at the main pipe inlet 2, while nothing substantial has been changed in the piping network 1 between the main pipe inlet 2 and the concerned pipe outlet PO₂.

The present invention is in no way limited to the embodiments of a method for optimizing or improving the energy efficiency of a system for pressurized fluid as described before, but such a method can be applied and be implemented in many different ways without departure from the scope of the invention.

The present invention is also not limited to embodiments of a data processing apparatus or computer, a compressor or a computer program as described in this text, but such a data processing apparatus or computer, such a compressor or such a computer program can be realized in very different manners without departure from the scope of the invention.

1-19. (canceled)

20. A method for optimizing or improving the efficiency of a system for pressurized fluid which comprises a pressurized piping network which is provided with a main pipe inlet and multiple pipe outlets which are located at user locations which are spaced from one another, wherein at the main pipe inlet of the piping network an inlet pressure is provided by a source of pressurized fluid of the system for pressurized fluid and wherein the piping network is subjected to a varying load at the pipe outlets due to varying demands of pressurized fluid during operation of user devices or appliances connected to the pipe outlets at the user locations, the method comprising the steps of:
a. determining for one or more pipe outlets the minimum pressure which is required at any time at the corresponding user location, so that operations at that user location can take place uninterruptedly;
b. determining a measuring period, corresponding to a typical duty cycle of the piping network, during which pressures at the main pipe inlet and the concerned pipe outlets will be measured;
c. measuring the pressures at the main pipe inlet and at the concerned pipe outlets during the measuring period;
d. calculating the difference during the measuring period between the possibly changing pressures at each concerned pipe outlet and the corresponding minimum pressure which is required at any time at the corresponding user location, so to find the corresponding overpressure at the concerned pipe outlet which is possibly varying during the measuring period;
e. finding for each concerned pipe outlet the minimal overpressure occurring during the measuring period so to obtain a series of minimal overpressures composed of the minimal overpressures of each concerned pipe outlet;
f. finding the smallest minimal overpressure occurring in the piping network during the measuring period;
g. evaluating whether the smallest minimal overpressure occurring in the piping network during the measuring period, is bigger than zero or not;
h. when the smallest minimal overpressure (SMO) is bigger than zero, making the proposal to decrease the inlet pressure of the piping network with an amount which is equal to or slightly larger or slightly smaller than the smallest minimal overpressure (SMO); and,
i. when the smallest minimal overpressure (SMO) is zero or lower than zero, making no further efforts for improving or optimizing the efficiency of the system for pressurized fluid or making an evaluation of one or more possible rearrangements to the piping network for increasing the energy efficiency of the system for pressurized fluid.

21. The method according to claim 20, wherein the pressures at the main pipe inlet and at the concerned pipe outlets are measured in a synchronous way during the measuring period in the step c.

22. The method according to claim 20, wherein the measurement of pressures during the measuring period in the step c of the method is a digital pressure measurement which is executed simultaneously at the different concerned pipe outlets and this at discrete points in time during the measuring period and that the calculations and finding in the steps d and e of the method are executed on this group of discrete digital measurements.

23. The method according to claim 20, wherein after executing the step h, in the case the smallest minimal overpressure (SMO) is bigger than zero, the inlet pressure is decreased by the proposed amount by adapting the pressure at the outlet of the source of pressurized fluid and the steps c-i of the method are repeated.

24. The method according to claim 20, wherein executing the step i, in the case the smallest minimal overpressure (SMO) is zero or smaller than zero, comprises an evaluation which involves a calculation of potential financial savings due to an increase in energy efficiency caused by a rearrangement of the piping network versus costs for rearranging the piping network.

25. The method according to claim 20, wherein the evaluation in the step i comprises the following steps of:
l. generating one or more theoretical piping networks (TPN) wherein a rearrangement or combination of rearrangements of the piping network has been applied;
m. calculating potential financial savings (PFS) for each possible rearrangement or combination of rearrangements of the piping network; and,
n. keeping the highest potential financial savings (PFS) and the corresponding rearrangement or combination of rearrangements of the piping network.

26. The method according to claim 25, wherein executing the step i comprises an evaluation of the usefulness of a rearrangement of the piping network which comprises an increase of a diameter of one or more parts of the piping network between the main pipe inlet and the pipe outlet where the smallest minimal overpressure (SMO) is measured and wherein a corresponding theoretical piping network (TPN) is generated in the step l.

27. The method according to claim 26, wherein the evaluation in the step i of the usefulness of said rearrangement of the piping network is only executed when the total duration, wherein the measured pressure at the concerned pipe outlet is lower than the minimum pressure which is required at any time at the corresponding user location (ULᵢ), exceeds a pre-determined period and wherein a corresponding theoretical piping network (TPN) is generated in step j.

28. The method according to claim 26, wherein executing the step i comprises an evaluation of the usefulness of a rearrangement of the piping network which comprises an insertion of one or more local buffer vessels in a part of the piping network between the main pipe inlet and the pipe outlet where the smallest minimal overpressure (SMO) is measured.

29. The method according to claim 28, wherein the evaluation in the step i of the usefulness of said rearrangement of the piping network is only executed when the total duration, wherein the measured pressure at the concerned pipe outlet is lower than the minimum pressure which is required at any time at the corresponding user location (ULᵢ), does not exceed a pre-determined period.

30. The method according to claim 25, wherein the step m of calculating potential financial savings (PFS) for each possible rearrangement or combination of rearrangements of the piping network comprises step q of the calculation of a theoretical minimum overpressure (TMO) which theoretically occurs in the corresponding theoretical piping network (TPN) wherein the concerned rearrangement or combination of rearrangements of the piping network has been applied and this at the pipe outlet where the smallest minimal overpressure (SMO) is measured in the piping network.

31. The method according to claim 30, wherein the calculation of potential financial savings (PFS) for a particular possible rearrangement or combination of rearrangements of the piping network in the step m comprises step r of deciding that the concerned rearrangement or combination of rearrangements of the piping network does not generate potential financial savings (PFS), when he theoretical minimum overpressure (TMO) is zero or smaller than zero, and, when the theoretical minimum overpressure (TMO) is greater than zero, comprises step s of calculating the potential financial savings when in the concerned theoretical piping network (TPN) the initial inlet pressure is decreased with an amount which is equal to the smallest of the theoretical minimum overpressure (TMO) and the second smallest minimal overpressure (SSMO) occurring in the piping network during the measuring period.

32. The method according to claim 31, wherein the steps q, r and s are repeated multiple times for different possible rearrangements or combinations of rearrangements of the piping network resulting in different potential financial savings (PFS) and wherein the rearrangement or combinations of rearrangement which is related to the highest potential financial savings is selected for implementation in step k.

33. The method according to claim 31, further comprising an additional step o in which the potential financial savings (PSF) or the highest potential financial savings together with the corresponding rearrangement or combination of rearrangements of the piping network is visualized to a user or an operator.

34. The method according to claim 20, wherein after implementation in step k of a rearrangement or combination of rearrangements of the piping network the steps c-i are again executed.

35. The method according to claim 20, wherein the method is executed with electronic means and/or is a computer-implemented method.

36. A data processing apparatus or computer, comprising a processor, which when executed, is adapted to perform the steps of the method of claim 20.

37. A compressor comprising a data processing apparatus or computer according to claim 36.

38. A non-transitory computer readable medium comprising a computer program comprising instructions which, when the program is executed by a computer, causes the computer to carry out the method of claim 20.
